(19) United States
(12) Patent Application Publication
(10) Pub. No.: US 2011/0024627 A1
(43) Pub. Date: Feb. 3, 2011

(54) Proximity Sensor with Ceramic Housing and Light Barrier

(75) Inventor: Yu Feng Yao, Singapore (SG)

Correspondence Address: Kathy Manke;Avago Technologies Limited, 4380 Ziegler Road, Fort Collins, CO, 80525, US

(73) Assignee: Avago Technologies ECBU (Singapore) Pte. Ltd., Fort Collins, CO (US)

(21) Appl. No.: 12/533,173

(22) Filed: Jul. 31, 2009

(51) Int. Cl. H01L 27/14; G01J 5/02; H05K 3/30; H01L 21/00

(52) U.S. Cl. 250/338.4; 250/353; 29/832; 438/25; 257/E21.002

(57) ABSTRACT

An optical proximity sensor is provided that comprises an infrared light emitter, an infrared light detector, a ceramic housing, a substrate, and a cover or shield. The ceramic housing is mounted on or attached to the substrate, and comprises first and second recesses separated by a light barrier. The cover is mounted over the ceramic housing, the light emitter and the light detector. The infrared light emitter is located within the first recess and mounted on the substrate. The infrared light detector is located within the second recess and mounted on the substrate. The light barrier between the first and second recesses, in conjunction with the remainder of the ceramic housing, the substrate, and the cover or shield substantially attenuates or blocks the transmission of undesired direct, scattered or reflected infrared light between the light emitter and the light detector, and thereby minimizes optical crosstalk and interference between the light emitter and the light detector.

### FIELD OF THE INVENTION

Various embodiments of the inventions described herein relate to the field of proximity sensors, and components, devices, systems and methods associated therewith.

### BACKGROUND

Optical proximity sensors, such as the AVAGO TECHNOLOGIES™ HSDL-9100 surface-mount proximity sensor, the AVAGO TECHNOLOGIES™ APDS-9101 integrated reflective sensor, the AVAGO TECHNOLOGIES™ APDS-9120 integrated optical proximity sensor, and the AVAGO TECHNOLOGIES™ APDS-9800 integrated ambient light and proximity sensor, are known in the art. Such sensors typically comprise an integrated high efficiency infrared emitter or light source and a corresponding photodiode or light detector, and are employed in a large number of hand-held electronic devices such as mobile phones, Personal Data Assistants (“PDAs”), laptop and portable computers, portable and handheld devices, amusement and vending machines, industrial automation machinery and equipment, contactless switches, sanitary automation machinery and equipment, and the like.

Referring to FIG. 1, there is shown a prior art optical proximity sensor 1 0 comprising infrared light emitter 16, light emitter driving circuit 51, light detector or photodiode 12, light detector sensing circuit 53, metal housing or shield 18 with apertures 55 and 57, and object to be sensed 60. Light rays 15 emitted by emitter 16 and reflected as light rays 19 from object 60 (which is in relatively close proximity to optical proximity sensor 10) are detected by photodiode 12 and thereby provide an indication that object 60 is close or near to sensor 10.

As further shown in FIG. 1, optical proximity sensor 10 further comprises metal housing or shield 18 formed of metal and comprising apertures 55 and 57 located over light emitter 16 and light detector 12, respectively, such that at least a first portion of light 15 emitted by light detector 12 passes through aperture 55, and at least a second portion of the first portion 19 of light reflected from object 50 in proximity to sensor 10 passes through aperture 57 for detection by light detector 12. As shown, metal housing or shield 18 may further comprise first and second modules 61 and 63 within which light emitter 16 and light detector 12 are disposed, respectively. The first and second modules 61 and 63 typically comprise adjoining optically opaque metal inner sidewalls 25 to provide optical isolation between first and second modules 61 and 63.

Many optical proximity sensors generally include a metal shield, such as shield or housing 18 of the type shown in FIG. 1, to provide optical isolation between light emitter 16 and light detector or photodiode 12 so that undesired optical cross-talk between emitter 16 and detector 12 is minimized. See, for example, the Data Sheets corresponding to the AVAGO TECHNOLOGIES™ APDS-9120 Integrated Optical Sensors Preliminary Datasheet and the AVAGO TECHNOLOGIES™ APDS-9800 Integrated Ambient Light and Proximity Sensors Preliminary Datasheet, each of which is hereby incorporated by reference herein, each in its respective entirety.

FIG. 2 shows a prior art optical proximity sensor 10 with metal shield or housing 18. The optical proximity sensor shown in FIG. 2 is an AVAGO TECHNOLOGIES™ APDS-9120 Integrated Optical Proximity Sensor, which contains a molded plastic substrate 11 upon which are mounted LED 16 and light detector or photodiode 12. Single-piece metal shield 18 covers LED 16 and light detector or photodiode 12 and contains a downwardly projecting light barrier 65 disposed therebetween (not shown in FIG. 2). Electrical contacts 17 provide a means to establish electrical connections between proximity sensor 10 and external devices. In the APDS-9120 optical proximity sensor, metal shield 18 is formed and thinned using conventional metal stamping techniques, and is affixed to the underlying plastic substrate 11 by gluing. The APDS-9120 sensor has an areal footprint of only 4 mm by 4 mm, and thus is quite small.

FIG. 3 shows a prior art optical proximity sensor 10 with a more complicated metal shield or housing 18 than that of FIG. 2. The optical proximity sensor shown in FIG. 3 is an AVAGO TECHNOLOGIES™ APDS-9800 Integrated Ambient Light and Proximity Sensor, which contains a printed circuit board (“PCB”) substrate 11 upon which are mounted LED 16, light detector or photodiode 12, and ambient light sensor 14. The two-piece metal shield 18 covers LED 16, light detector or photodiode 12, and ambient light sensor 14 and contains a downwardly projecting light barrier 65 disposed therebetween. In the APDS-9800 optical proximity sensor, metal shield 18, being of a considerably more complicated shape and geometry than that of FIG. 2, is formed and thinned using more advanced progressive metal stamping techniques, and must be hand-fitted and attached to the underlying PCB by gluing to ensure proper alignment and fit.

Referring now to FIG. 4, there is shown an optical proximity sensor 10 comprising light emitter 16 mounted on substrate 11 and separated from light detector 12 by light barrier 25, which is formed of polyimide or another suitable polymeric material. An optically transmissive material 21 is employed to fill cavities 31 and 37, which is typically a single mold two-part epoxy or transfer molding compound. As shown in FIG. 4, while light rays 15 are transmitted through material 21, other reflected, diffracted or refracted IR radiation 19 can leak across light barrier 25 to light detector 12 through single mold compound 21 or light barrier 25, which manifests itself as undesired crosstalk or interference between light emitter 16 and light detector 12, thereby degrading the performance of proximity sensor 10. The amount of reflected, diffracted or refracted IR radiation 19 and undesired crosstalk or interference between light emitter 16 and light detector 12 is typically exacerbated by the presence of window 23, which in some applications is provided as part of the portable or other type of electronic device in which proximity sensor 10 is housed and mounted.

Some of the problems arising from undesired crosstalk or interference caused by reflected, diffracted or refracted IR radiation 19 shown in FIG. 4 may be reduced by disposing a metal light barrier 25 between light emitter 16 and light detector 12. Providing such a metal barrier 25 in proximity sensor 10, however, presents problems respecting increased manufacturing costs and complexity.

As will now be seen, at least some optical proximity sensors of the prior art rely upon the use of an externally mounted metal shield 18 of a rather complicated shape and geometry, which is required to reduce the amount of crosstalk or interference that might otherwise occur between LED 16 and light detector 12, as well as to help increase the detection distance of the device. Such metal shields 18 are often quite small, however, making them difficult to manufacture in high volumes, and thus expensive to fabricate. Metal shields 18 also generally require expensive automated equipment to attach same to sensors 10 in a mass production setting. Moreover, the quality of metal shields 18 often varies, and issues commonly arise with suppliers being unable to meet the tight dimensional tolerances required for such small devices. Metal shields 18 can also detach from sensor 10, thereby adding another failure point for sensor 10. Other types of light barriers provided in sensors 10 between IR light sources and 16 and light detectors 16, such as molded plastic or polyimide light barriers, also have not bee completely successful in preventing the transmission of undesired IR radiation therethrough or therearound.

What is need is an optical proximity sensor design that features improved eliminates the need to include a metal shield 18 of complicated, but which features high crosstalk and interference rejection characteristics so that an optical proximity sensor can be provided that features improved performance, lower cost, increased manufacturability and improved reliability.

### SUMMARY

In some embodiments, there is provided an optical proximity sensor comprising a substrate, a housing comprising ceramic and having first and second recesses formed therein separated by a light barrier, the housing being attached to the substrate, an infrared light emitter located in the first recess and mounted on the substrate, the light emitter being operably connected to and driven by a light emitter driving circuit, a light detector located in the second recess and mounted on the substrate, the light detector being operably connected to and driven by a detector sensing circuit, and a cover located over and attached to the housing, the cover having first and second apertures formed therein that correspond, respectively, to the locations of the infrared light emitter and the light detector disposed therebelow, where at least a first portion of light emitted by the light detector passes through the first aperture, and at least a second portion of the first portion of light reflected from an object of interest in proximity to the sensor passes through the second aperture for detection by the light detector, and the ceramic housing and light barrier substantially attenuate or block the transmission of undesired direct, scattered or reflected infrared light between the light emitter and the light detector and thereby minimize optical crosstalk and interference between the light emitter and the light detector.

In other embodiments, there is provided a method of making an optical proximity sensor comprising mounting an infrared light emitter on a substrate, mounting an infrared light detector on the substrate, the infrared light detector being spaced apart from the infrared light emitter on the substrate, attaching a housing comprising ceramic and having first and second recesses formed therein separated by a light barrier over the substrate, and attaching a cover over the ceramic housing, the cover having first and second apertures formed therein that correspond, respectively, to the locations of the infrared light emitter and the light detector disposed therebelow.

Further embodiments are disclosed herein or will become apparent to those skilled in the art after having read and understood the specification and drawings hereof.

### BRIEF DESCRIPTION OF THE DRAWINGS

Different aspects of the various embodiments of the invention will become apparent from the following specification, drawings and claims in which:

FIG. 1 shows a prior art optical proximity sensor and associated circuitry;

FIG. 2 shows a prior art optical proximity sensor with a metal shield or housing;

FIG. 3 shows a prior art optical proximity sensor with a more complicated metal shield or housing than that shown in FIG. 2;

FIG. 4 shows an optical proximity sensor comprising a light emitter mounted on a substrate and separated from a light detector by a polyimide light barrier;

FIG. 5 shows a top perspective view of one embodiment of a proximity sensor 10 with light emitter 12, ambient light sensor 14, light detector 12, and integrated circuit 35 mounted on ceramic substrate 11;

FIG. 6 shows a top perspective view of the proximity sensor 10 of FIG. 5 with optically transparent material 21 disposed in recesses 31 and 37;

FIG. 7 shows a top perspective view of the proximity sensor 10 of FIG. 6 with shield or cover 18 positioned thereover;

FIG. 8 shows a bottom plan view of one embodiment of ceramic substrate 11;

FIG. 9 shows a top perspective view of proximity sensor 10 before light emitter 12, ambient light sensor 14, light detector 12, or integrated circuit 35 have been mounted on ceramic substrate 11;

FIG. 10 shows a top plan view of proximity sensor 10 after light emitter 12, ambient light sensor 14, light detector 12, or integrated circuit 35 have been mounted on ceramic substrate 11;

FIG. 11 shows a top perspective view of proximity sensor 10 after shield or cover 18 has been mounted atop ceramic housing 15;

FIG. 12 illustrates one embodiment of a method of making an optical proximity sensor, and

FIG. 13 illustrates comparative optical transmittances of a ceramic semiconductor package versus a conventional printed circuit board (“PCB”) semiconductor package.

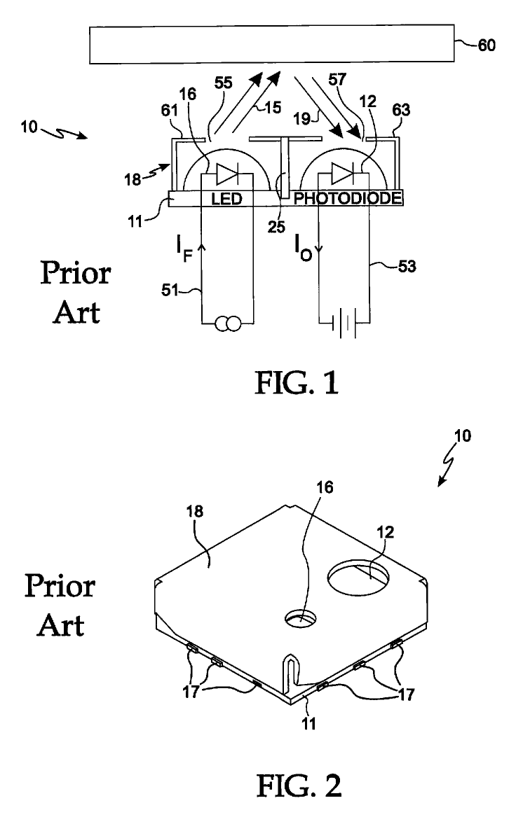

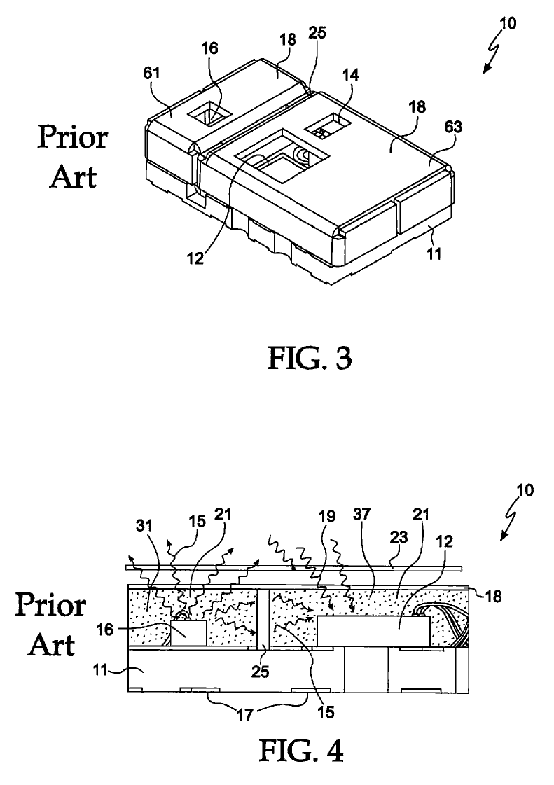

The drawings are not necessarily to scale. Like numbers refer to like parts or steps throughout the drawings, unless otherwise noted.

### DETAILED DESCRIPTION OF SOME PREFERRED EMBODIMENTS

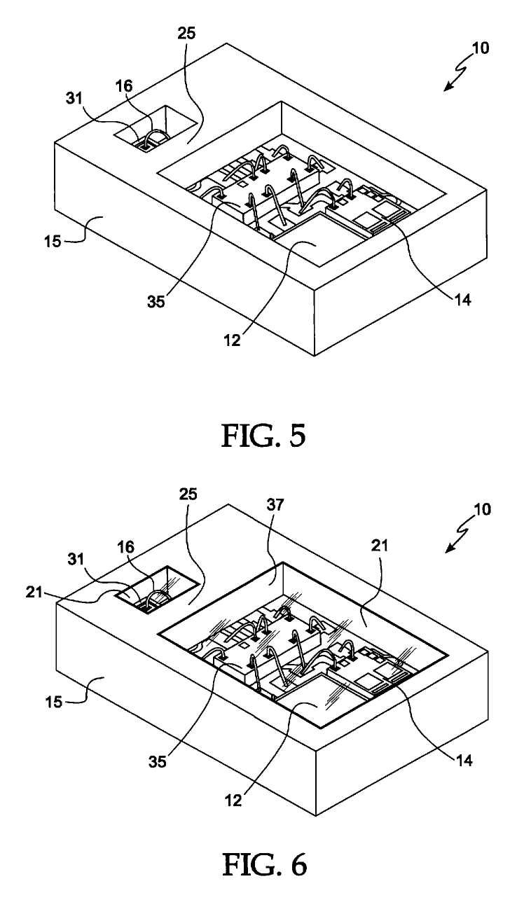

Referring now to FIG. 4, there is shown an optical proximity sensor 10 comprising light emitter 16 mounted on ceramic substrate 11 and separated from light detector 12, also mounted on ceramic substrate 11, by ceramic light barrier 25, which forms a portion of ceramic housing 15. Ceramic housing 15 is disposed over ceramic substrate 11, and has two separate recesses 31 and 37 formed therein, which as shown in FIG. 5 are separated by light barrier 25. In a preferred embodiment, ceramic housing 15 is a single unitary piece of ceramic having recesses 31 and 37 formed therein, and is glued or otherwise attached to ceramic substrate 11. In one embodiment, substrate 11 is a printed circuit board or molded plastic substrate.

FIG. 5 further shows ambient light sensor 14 and application specific integrated circuit (“ASIC”) 35 mounted on ceramic substrate 11. In one embodiment, light emitter 16, light detector 12, ambient light sensor 14 and ASIC 35 are die bonded to ceramic substrate 11, followed by wire bonding. Light emitter 16 is preferably an IR LED, such as a TYNTEK™ TK 114IRA infrared AlGaAs semiconductor chip. Light detector 12 is preferably a photodiode chip such as a TYNTEK™ K 043PD silicon photodiode semiconductor. Ambient light sensor 14 is preferably a photodiode chip such as an AVAGO TECHNOLGIES™ APDS-9005 Miniature Surface-Mount Ambient Light Photo Sensor, the Data Sheet for which is submitted in an Information Disclosure Statement on even date herewith, and which is hereby incorporated by reference herein in its entirety. According to one embodiment, ASIC 35 is an AVAGO TECHNOLOGIES™ ARGUS™ APDS-9701 Signal Conditioning IC for Digital Proximity Sensors (I2C interface), the Preliminary Data Sheet for which is submitted in an Information Disclosure Statement on even date herewith, and which is hereby incorporated by reference herein in its entirety. Note, however, that integrated circuit or ASIC 35 may be or include any suitable processor, CPU, controller, micro-processor, processing circuit, DSP or other processing circuitry.

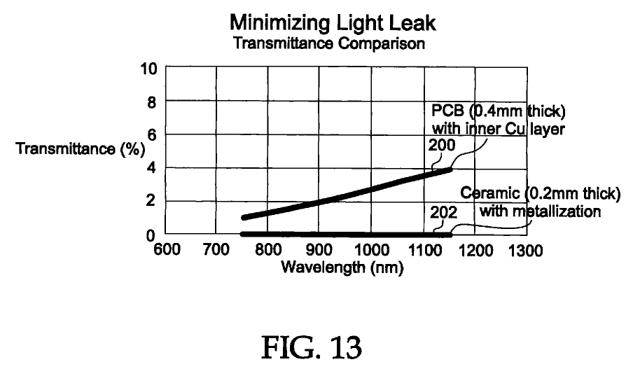

Ceramic housing 15 and ceramic substrate 11 are formed using ceramic electronic manufacturing and packaging techniques and materials well known to those skilled in the art, more about which is said below. In an IC packaging context, the ceramic materials from which ceramic housing 15 and ceramic substrate are formed provide several advantages over plastic molded or other types of conventional packaging, including lower levels of trichloroethylene (“TCE”), increased mechanical strength, high thermal conductivity, increased design flexibility, higher dielectric constant, and an increased degree of infra-red (“IR”) optical isolation and absorption that ceramic has been discovered to provide between light emitter 16 and light detector 12. Under some circumstances it can also be easier to hermetically seal ceramic packages than polyimide molded packages. Experiments between otherwise identical proximity sensor packages made using ceramic on the one hand, and polyimide molding on the other hand, showed that the proximity sensor having a ceramic substrate and a ceramic housing featured considerably improved rejection and isolation of undesired IR radiation compared to the polyimide encapsulated proximity sensor (see, for example, FIG. 13, where the IR transmittance of semiconductor packages made using printed circuit board (“PCB”) and ceramic substrates are compared.

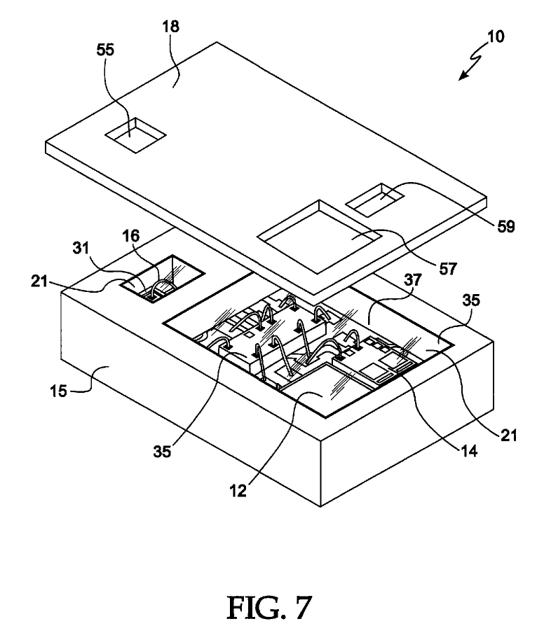

Referring now to FIG. 6, there is shown proximity sensor 10 after optically transmissive material 21 has been used to fill recesses 31 and 37. In one embodiment, optically transmissive material 21 is a single mold two-part epoxy or transfer molding compound. While light rays 15 are transmitted through material 21 form light emitter 12, but for ceramic housing 15 other reflected, diffracted or refracted IR radiation 19 could leak across to light detector 12 through single mold compound 21, which would manifest itself as undesired crosstalk or interference between light emitter 16 and light detector 12, thereby degrading the performance of proximity sensor 10. Owing to the highly-desirable IR-absorbing and IR-containing characteristics of ceramic housing 15, such undesired crosstalk or interference is substantially eliminated, especially after shield or cover 18 has been mounted above ceramic housing 15 and recesses 31 and 37 (see FIG. 7). Shield or cover 18 is preferably formed of a single piece of stamped metal with appropriate windows 55, 57 and 59 formed therein, and may be glued or otherwise attached to the top portions of ceramic housing 15. In one embodiment, shield or cover 18 is covered or painted with an IR-absorbing black paint or coating to further reduce the probability of crosstalk or interference occurring.

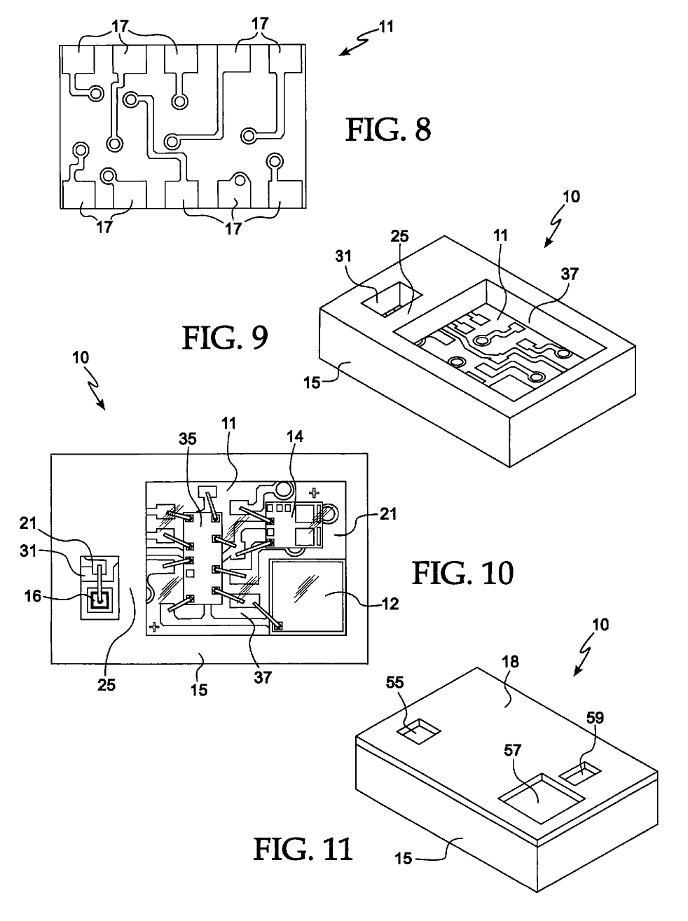

FIG. 8 illustrates one embodiment of the underside of ceramic substrate 11, where contacts 17 are configured to provide electrical connections between proximity sensor 10 and external devices. FIG. 9 shows one embodiment of proximity sensor 10 before light emitter 12, light detector 16, ambient light sensor 14 or integrated circuit 35 are mounted on substrate 11. FIG. 10 shows a top plan view of proximity sensor 10 after light emitter 12, light detector 16, ambient light sensor 14 and integrated circuit 35 have been mounted on substrate 11. FIG. 11 shows optical proximity sensor 10 after cover or shield 18 has been mounted atop ceramic housing 15.

It will now be seen that FIGS. 5 through 11 illustrate one embodiment of a proximity sensor 10 that provides solutions to at least some of the problems of prior art proximity sensors described above, where metal or polyimide barrier 25 is replaced with ceramic barrier 25. Total Internal Reflection (“TIR”) within recesses 31 and 37 helps improve the performance of proximity sensor 10. Ceramic barrier 25, in conjunction with the geometry of recesses 31 and 37, the positioning of light emitter 12 and light detector 16 respecting one another, other portions of ceramic housing 15, and shield or cover 18 substantially attenuates or blocks the transmission of undesired direct, scattered or reflected light between light emitter 16 and light detector 12, and thereby minimizes optical crosstalk and interference between light emitter 16 and light detector 12. Note that optical lenses, preferably formed of the same material as optically transmissive material 21, and formed at the same time during the manufacturing process as optically transmissive material 21, may also be disposed over light emitter 16 and light detector 12, respectively.

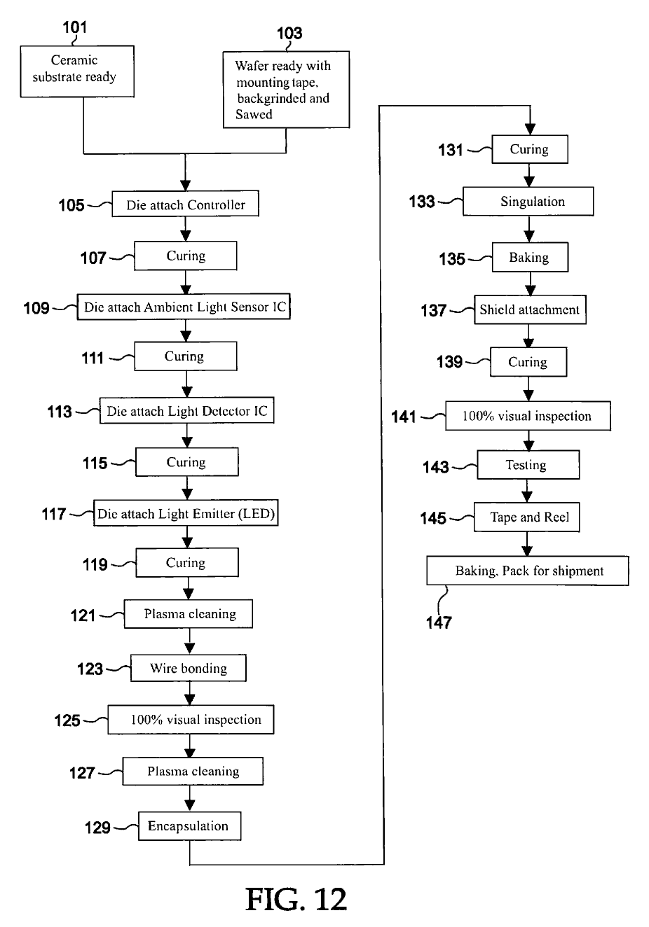

Referring now to FIG. 12, there is shown one embodiment of a method of making proximity sensor 10. At step 101 ceramic PCB 11 is readied, and at sep 103 semiconductor wafers of a controller such as an AVAGO TECHNOLOGIES™ ARGUS™ APDS-9701 Signal Conditioning IC, a TYNTEK™ TK 114IRA infrared AlGaAs semiconductor chip, a TYNTEK™ TK 043PD silicon photodiode semiconductor, and an AVAGO TECHNOLGIES™ APDS-9005 Miniature Surface-Mount Ambient Light Photo Sensor are readied. Preferably, all such semiconductor wafers have been mounted on blue mounting tape, backgrinded and diced. Next, at step 105 a first pass of die attachment is carried out for the ARGUS IC using electrically non-conductive epoxy (such as ABLESTIK 2025) to attach the ARGUS IC to substrate 11. The epoxy is cured at step 107. A second pass of die attachment is carried out at step 109, where the 9005 IC is attached to substrate 11 using electrically non-conductive epoxy, which is then cured at step 111. A third pass of die attachment is carried out at step 113, where the TK043 PD is attached to substrate 11 with an electrically conductive epoxy (such as FDP5053 or FDP5100), which is then cured at step 115. A final pass of die attachment is carried out at step 117 where the LED is attached to substrate 11 using an electrically conductive epoxy such as FDP5053 or FDP5100, followed by epoxy curing at step 119. Plasma cleaning is carried out at step 121 to clean the surface of ceramic PCB 11, and especially the bonding surfaces thereof, after which wire bonding is carried out at step 123. After wire bonding, 100% visual inspection is conducted at step 125 to verify the integrity of the bonded wires. After visual inspection, a second plasma cleaning step is conducted at step 127. After cleaning, an epoxy encapsulation step is carried out at step 129 to place optically transmissive material 21 in recesses 31 and 37 conducted, followed by epoxy curing. After the epoxy has cured, the ceramic PCB are singulated at step 133 to provide individual packages, which according to one embodiment are then baked at 100 degrees Centigrade for four hours in step 135. After baking, a cover or shield 18 is attached to each package at step 137 using electrically non-conductive glue (e.g. 3M EW3020), which is then cured at step 139. Next, at step 141 a 100% visual inspection of each package is conducted, after which electrical testing of each package is carried out at step 143. After testing, individual packages that have been found to be good are packed onto a tape and reel, and then the packages are baked on the tape and reel at according to one embodiment are then baked at 100 degrees Centigrade for four hours in step 147, after which the packages are ready to be packed and shipped. Those skilled in the art will understand that the various steps described above may be modified, and in some cases their order changed, without departing from the scope of the invention. For example, ceramic baking times and temperatures may be changed according to the particular type of ceramic tape that is being used and other factors.

As mentioned above, FIG. 13 compares the IR transmittance of semiconductor packages made using printed circuit board (“PCB”) and ceramic substrates. As shown, the ceramic packages features substantially lower IR transmittance characteristics than the conventional PCB package. In the context of FIG. 13, the term “PCB” is intended to mean a printed circuit board that does not contain ceramic and that comprises materials conventionally employed in PCBs such as fiberglass, glass, plastic, polymers, or other fibrous, vitreous o polymeric materials that have long been used in the manufacture of PCBs.

Included within the scope of the present invention are methods of making and having made the various components, devices and systems described herein.

Various embodiments of the invention are contemplated in addition to those disclosed hereinabove. The above-described embodiments should be considered as examples of the present invention, rather than as limiting the scope of the invention. In addition to the foregoing embodiments of the invention, review of the detailed description and accompanying drawings will show that there are other embodiments of the invention. Accordingly, many combinations, permutations, variations and modifications of the foregoing embodiments of the invention not set forth explicitly herein will nevertheless fall within the scope of the invention.

We claim:

1. An optical proximity sensor, comprising:
a substrate;
a housing comprising ceramic and having first and second recesses formed therein separated by a light barrier, the housing being attached to the substrate;
an infrared light emitter located in the first recess and mounted on the substrate, the light emitter being operably connected to and driven by a light emitter driving circuit;
a light detector located in the second recess and mounted on the substrate, the light detector being operably connected to and driven by a detector sensing circuit, and
a cover located over and attached to the housing, the cover having first and second apertures formed therein that correspond, respectively, to the locations of the infrared light emitter and the light detector disposed therebelow;
wherein at least a first portion of light emitted by the light detector passes through the first aperture, and at least a second portion of the first portion of light reflected from an object of interest in proximity to the sensor passes through the second aperture for detection by the light detector, and the ceramic housing and light barrier substantially attenuate or block the transmission of undesired direct, scattered or reflected infrared light between the light emitter and the light detector and thereby minimize optical crosstalk and interference between the light emitter and the light detector.

2. The optical proximity sensor of claim 1, wherein the light emitter driving circuit is mounted on the substrate.

3. The optical proximity sensor of claim 1, wherein the detector sensing circuit is mounted on the substrate.

4. The optical proximity sensor of claim 1, further comprising an ambient light sensor located in the second recess.

5. The optical proximity sensor of claim 4, wherein the cover further comprises a third aperture formed therein that corresponds to the location of the ambient light sensor disposed therebelow;

6. The optical proximity sensor of claim 4, wherein the ambient light sensor is a semiconductor die.

7. The optical proximity sensor of claim 1, wherein the substrate comprises ceramic.

8. The optical proximity sensor of claim 1, wherein the substrate comprises a printed circuit board (“PCB”).

9. The optical proximity sensor of claim 1, wherein the substrate further comprises a plurality of electrically conductive traces disposed thereon or therewithin.

10. The optical proximity sensor of claim 1, further comprising an optically transmissive material disposed within and substantially filling the first recess.

11. The optical proximity sensor of claim 1, further comprising an optically transmissive material disposed within and substantially filling the second recess.

12. The optical proximity sensor of claim 1, wherein at least one of the light emitter and light detector is a semiconductor die.

13. The optical proximity sensor of claim 1, further comprising at least one integrated circuit operably connected to the light emitter and the light detector, and configured to control the operation of the light detector and the light detector, and to process output signals provided by the light detector.

14. The optical proximity sensor of claim 13, wherein the at least one integrated circuit further comprises a proximity sensor application specific integrated circuit (ASIC).

15. The optical proximity sensor of claim 1, wherein the optical proximity sensor is incorporated into a portable electronic device.

16. The optical proximity sensor of claim 15, wherein the portable electronic device is a mobile telephone, a personal data assistant (PDA), a laptop computer, a notebook computer, or a computer.

17. The optical proximity sensor of claim 1, wherein the light emitter is an LED.

18. The optical proximity sensor of claim 1, wherein the light detector is a positive-intrinsic-negative (“PIN”) diode.

19. The optical proximity sensor of claim 1, wherein a molded optically transmissive lens is formed over the light emitter or the light detector.

20. A method of making an optical proximity sensor, comprising:
mounting an infrared light emitter on a substrate;
mounting an infrared light detector on the substrate, the infrared light detector being spaced apart from the infrared light emitter on the substrate;
attaching a housing comprising ceramic and having first and second recesses formed therein separated by a light barrier over the substrate, and
attaching a cover over the ceramic housing, the cover having first and second apertures formed therein that correspond, respectively, to the locations of the infrared light emitter and the light detector disposed therebelow.

21. The method of claim 20, further comprising substantially filling the first and second recesses with an optically transmissive material.

22. The method of claim 20, further comprising forming optically transmissive lenses over the light emitter and the light detector.

23. The method of claim 20, wherein the light emitter or the light detector is die-attached to the substrate.

24. The method of claim 20, wherein the light emitter or the light detector is wire-bonded to the substrate.

24. The method of claim 20, further comprising attaching an integrated circuit comprising an ambient light sensor to the substrate.
